(19) United States
(12) Patent Application Publication
(10) Pub. No.: US 2006/0043496 A1
(43) Pub. Date: Mar. 2, 2006

(54) Semiconductor device and method for fabricating the same

(75) Inventors: Yasuhiro Kunimasa, Osaka (JP); Mizuki Segawa, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/153,498

(22) Filed: Jun. 16, 2005

(30) Foreign Application Priority Data
Aug. 27, 2004 (JP) 2004-248943

(51) Int. Cl. H01L 29/76

(52) U.S. Cl. 257/388

(57) ABSTRACT

A semiconductor device includes: an active region formed in a substrate and surrounded with an isolation formed in the substrate; a gate electrode formed above the active region and made of a semiconductor material; and an interconnect formed on the isolation and in the same layer as the gate electrode and made of the same material as the gate electrode. Side surfaces of the gate electrode are formed with insulating sidewalls, respectively. Upper surfaces of the gate electrode and the interconnect and side surfaces of at least a portion of the interconnect are formed with silicide layers, respectively.

### CROSS-REFERENCE TO RELATED APPLICATIONS

This application claims priority under 35 U.S.C. § 119 on Patent Application No. 2004-248943 filed in Japan on Aug. 27, 2004, the entire contents of which are hereby incorporated by reference.

### BACKGROUND OF THE INVENTION

1. Fields of the Invention

The present invention relates to semiconductor devices and methods for fabricating the device. In particular, the present invention relates to semiconductor devices in which a silicide layer is formed on a surface of a gate electrode made of polysilicon or the like, and to methods for fabricating such a device.

2. Description of Related Art

Recently, semiconductor devices have had higher packing densities, more enhanced functionalities, and faster processing speed. With such a trend, the devices have been requested to decrease the resistances of gate electrodes and gate contacts (connecting portions between the gate electrodes and contact plugs connected thereto). To meet this request, the devices employ gate electrode structures in which a silicide layer (such as a titanium silicide layer or a cobalt silicide layer) is formed on a polysilicon layer serving as the gate electrode (see, for example, Japanese Patent No. 2820122, and Japanese Unexamined Patent Publications No. 2001-77210 and No. H9-162397).

FIG. 16 is a plan view showing one typical structure of conventional semiconductor devices having this gate electrode structure. FIGS. 17A to 17C are sectional views showing process steps of one of fabrication methods of the conventional semiconductor device in FIG. 16, which are taken along the line XVI-XVI in FIG. 16.

The fabrication method of the conventional semiconductor device shown in FIG. 16 is as follows. First, as shown in FIG. 17A, an isolation insulating film 12 for electrically isolating elements from each other is formed on a semiconductor substrate 11. Then, a gate insulating film 13 is formed on a region of the semiconductor substrate 11 surrounded with the isolation insulating film 12, that is, on an active region serving as an element formation region. Subsequently, a polysilicon film that will be formed into a gate electrode is deposited over the entire surface of the semiconductor substrate 11, and then the deposited polysilicon film is patterned by a known photolithography method and a known dry etching method to form a gate electrode 14a above the active region with the gate insulating film 13 interposed therebetween. In this formation, on the isolation insulating film 12, a gate interconnect 14b is formed which is connected to the gate electrode 14a. By ion implantation, first doped layers 16 serving as extension regions are formed in portions of the active region located below both sides of the gate electrode 14a.

As shown in FIG. 17B, by the techniques of depositing and etching an insulating layer, insulating sidewalls 15 are formed on side surfaces of the gate electrode 14a and the gate interconnect 14b. Next, by ion implantation, second doped layers 17 serving as source and drain regions are formed in portions of the active region located below the both sides of the gate electrode 14a.

As shown in FIG. 17C, for example, a titanium film is deposited over the semiconductor substrate 11, and then annealing is performed to allow silicon forming the gate electrode 14a, the gate interconnect 14b, and the semiconductor substrate 11 to react with portions of the titanium film in contact with the silicon, thereby producing titanium silicide. Thereafter, an unreacted titanium film is selectively removed to form silicide layers 18 on the upper surfaces of the gate electrode 14a and the gate interconnect 14b and the surfaces of the second doped layers 17 serving as the source and drain regions. An interlayer insulating film 19 is then deposited over the semiconductor substrate 11. In the manner described above, the conventional semiconductor device shown in FIG. 16 is completed. Note that illustration of the silicide layer 18 and the interlayer insulating film 19 is omitted in FIG. 16.

By employing the fabrication method described above, the surface portions of the gate electrode and the gate interconnect (which are combinedly referred to as gate electrode wiring) and the surface portions of the source and drain regions are silicided in a self-aligned manner. Therefore, resistances of the gate electrode wiring, the gate contact, and the like can be lowered, which offers speed enhancement of the device.

### SUMMARY OF THE INVENTION

However, in a fine process for fabricating a device whose gate electrode wiring has a line width of about 0.35 μm or smaller, heat treatment or the like at high temperatures in a fabrication process of the device may induce stress at the interface between the gate electrode wiring and a silicide layer formed on the upper surface thereof. This stress may in turn cause exfoliation or a break of the silicide layer. In addition, the heat treatments described above or the like may induce silicide cohesion, which may cause a local break of the silicide layer on the gate electrode wiring. In particular, in a semiconductor device having a dual gate structure in which n- and p-type gate electrodes containing n- and p-type impurities introduced by ion implantation into a silicon layer serving as the gate electrodes, respectively, are connected to each other, the silicide layer formed on the boundary portion (connection portion) between the n- and p-type gate electrodes is likely to be broken, so that the resistance of the gate electrode is easily increased.

In the case where the conventional technique shown in FIGS. 16 and 17A to 17C is employed, if a contact plug 20 is formed above the gate interconnect 14b on the isolation insulating film 12 in order to make an electrical contact with the gate interconnect 14b, the position of the contact plug 20 may deviate relative to the gate interconnect 14b as shown in FIG. 18. In this structure, if a portion of the contact plug 20 deviates from the gate interconnect 14b, the contact area of the gate interconnect 14b with the contact plug 20 is decreased. This causes a problem of an increase in contact resistance therebetween.

In order to ensure a sufficient contact area of the gate interconnect with the contact plug even though the position of the contact plug deviates, as shown in FIG. 19, it can be considered that a design rule about the contact portion of the gate interconnect 14b is provided with a margin region for the deviation having a fixed area. In this case, however, it is difficult to decrease the distance between adjacent lines of the gate electrode wiring, which restricts reduction of the chip area of the device. Moreover, in this case, when the margin region for the deviation from the gate interconnect 14b is formed, the edges of the silicon layer serving as the margin region are likely to cause tailing toward the active region. This easily causes, at the active region edge, fluctuations of the dimension (widening) of the gate electrode 14a.

With the foregoing in mind, an object of the present invention is to provide a semiconductor device capable of: preventing resistance rise of gate electrode wiring affected by a break of a silicide layer on the gate electrode wiring; and preventing resistance rise of a gate contact caused by possible deviation of the position of the contact relative to the gate electrode wiring while no margin region for taking measures against the contact-position deviation is added to a design rule about the gate electrode wiring, and to provide a method for fabricating such a device.

To attain this object, a semiconductor device according to the present invention includes: an active region formed in a substrate and surrounded with an isolation formed in the substrate; a gate electrode formed above the active region and made of a semiconductor material; and an interconnect formed on the isolation and in the same layer as the gate electrode and made of the same material as the gate electrode. In this device, side surfaces of the gate electrode are formed with insulating sidewalls, respectively, and upper surfaces of the gate electrode and the interconnect and side surfaces of at least a portion of the interconnect are formed with silicide layers, respectively.

Note that in the present invention, an interconnect formed in the same layer as a gate electrode refers to: a gate interconnect directly connected to the gate electrode on an active region; and an interconnect, a resistor, or the like electrically connected to gate electrode wiring, source and drain regions, or the like through another interconnect provided in a different layer from the gate electrode. Any of them is formed in the same step as the formation step of the gate electrode. In addition, the term “gate electrode wiring” used in the following description includes “an interconnect or a resistor” formed in the same layer as the gate electrode.

In the semiconductor device of the present invention, the silicide layer is formed also on the side surface of the interconnect such as the gate interconnect located on the isolation. That is to say, on the side surface of that interconnect, the sidewall has been removed and thus not only the upper surface but also the side surface of the interconnect is silicided. Therefore, as compared to the conventional device structure in which only the upper surface of the gate electrode wiring is silicided, the area of the silicided region is greater by the area of the silicided side surface of the interconnect. This reduces the resistance of the gate electrode wiring and prevents resistance rise of the gate electrode wiring resulting from a break of the silicide layer on the gate electrode wiring.

In the semiconductor device of the present invention, if a contact plug is formed on a portion of the interconnect whose side surface is formed with the silicide layer, the following effects can be provided. Even if the position of the contact plug deviates relative to the interconnect such as the gate interconnect and thus a portion of the contact plug is located off the gate interconnect, the contact area of the gate interconnect with the contact plug can be secured on both the upper and side surfaces of the gate interconnect. This avoids the trouble in which the contact resistance therebetween increases. In addition, in the conventional technique, in order to secure a sufficient contact area of the gate interconnect with the contact plug, a design rule about the contact portion of the gate interconnect has to be provided with a margin region for the deviation having a fixed area. However, with the device of the present invention, there is no need to provide such a region. This facilitates a decrease in the distance between the adjacent lines of the gate electrode wiring, so that the chip area of the device can be reduced.

Preferably, in the above case, the contact plug is connected to at least a portion of the silicide layer formed on the side surface of the interconnect. Thus, the contact resistance can be reduced.

Preferably, in the above case, the contact plug is connected to the silicide layers formed on both side surfaces of the interconnect. Thus, the contact resistance can be further reduced.

In the semiconductor device of the present invention, the silicide layer may be formed on the entire upper and side surfaces of the interconnect.

In the semiconductor device of the present invention, the interconnect may be a resistor interconnect, and the silicide layer may be formed on at least side surfaces of contact formation regions located at both ends of the interconnect, the both ends interposing a resistor region of the interconnect. In this case, if the insulating sidewalls are formed on side surfaces of the resistor region of the interconnect, respectively, the silicide layer can be prevented from being formed on the side surfaces of the resistance region. Moreover, if an anti-silicidation film is formed to cover an upper surface of the resistor region of the interconnect, the silicide layer can be prevented from being formed on the upper surface of the resistance region.

In the semiconductor device of the present invention, if a portion of the interconnect whose side surface is formed with the silicide layer is a connecting portion between n- and p-type gate electrodes of a dual gate structure, the following effects can be provided. Since the silicide layer is formed also on the side surface of the interconnect such as the gate interconnect, the area of the silicided region is greater than that of the conventional device structure in which only the upper surface of the gate electrode wiring is silicided. Moreover, since the portion of the interconnect whose side surface is formed with the silicide layer is located at the connecting portion between the n- and p-type gate electrodes of the dual gate structure, the area of the silicided region of the connecting portion is increased. Therefore, resistance rise of the gate electrode wiring resulting from a break of the silicide layer of the connecting portion can be prevented.

In the semiconductor device of the present invention, a gate insulating film may be formed between the active region and the gate electrode.

In the semiconductor device of the present invention, impurity layers may be formed in portions of the active region located below both sides of the gate electrode, respectively.

In the semiconductor device of the present invention, the semiconductor material forming the gate electrode and the interconnect may be polysilicon or amorphous silicon.

A method for fabricating a semiconductor device according to the present invention includes: the step (a) of forming, in a substrate, an isolation and an active region surrounded with the isolation; the step (b) of forming, above the active region, a gate electrode made of a semiconductor material, and simultaneously forming, on the isolation and in the same layer as the gate electrode, an interconnect made of the same material as the gate electrode; the step (c) of forming insulating sidewalls on side surfaces of the gate electrode and the interconnect; the step (d) of removing the insulating sidewalls formed on side surfaces of at least a portion of the interconnect; and the step (e) of forming, after the step (d), silicide layers on upper surfaces of the gate electrode and the interconnect and on portions of side surfaces of the interconnect on which the insulating sidewalls have been removed.

In the method for fabricating a semiconductor device according to the present invention, of the insulating sidewalls formed on the side surfaces of the gate electrode wiring, those formed on side surfaces of the interconnect such as the gate interconnect on the isolation are removed. Thus, not only the upper surface but also the side surface of that interconnect can be silicided. Therefore, as compared to the conventional device structure in which only the upper surface of the gate electrode wiring is silicided, the area of the silicided region is greater by the area of the silicided side surface of the interconnect. This reduces the resistance of the gate electrode wiring and prevents resistance rise of the gate electrode wiring resulting from a break of the silicide layer on the gate electrode wiring.

If the method for fabricating a semiconductor device according to the present invention further includes, after the step (e), the step of forming a contact plug on a portion of the interconnect whose side surface is formed with the silicide layer, the following effects can be provided. Even if the position of the contact plug deviates relative to the interconnect such as the gate interconnect and thus a portion of the contact plug is located off the gate interconnect, the contact area of the gate interconnect with the contact plug can be secured on both the upper and side surfaces of the gate interconnect. This avoids the trouble in which the contact resistance therebetween increases. In addition, in the conventional technique, in order to secure a sufficient contact area of the gate interconnect with the contact plug, a design rule about the contact portion of the gate interconnect has to be provided with a margin region for the deviation having a fixed area. However, with the method of the present invention, there is no need to provide such a region. This facilitates a decrease in the distance between adjacent lines of the gate electrode wiring, so that the chip area of the device can be reduced.

In the method for fabricating a semiconductor device according to the present invention, if a portion of the interconnect whose side surface is formed with the silicide layer is a connecting portion between n- and p-type gate electrodes of a dual gate structure, the following effects can be provided. Since the silicide layer can be formed also on the side surface of the interconnect such as the gate interconnect, the area of the silicided region is greater than that of the conventional device structure in which only the upper surface of the gate electrode wiring is silicided. Moreover, since the portion of the interconnect whose side surface is formed with the silicide layer is located at the connecting portion between the n- and p-type gate electrodes of the dual gate structure, the area of the silicided region of the connecting portion is increased. Therefore, resistance rise of the gate electrode wiring resulting from a break of the silicide layer of the connecting portion can be prevented.

The method for fabricating a semiconductor device according to the present invention may further include, between the steps (a) and (b), the step of forming a gate insulating film on the active region.

The method for fabricating a semiconductor device according to the present invention may further include, between the steps (c) and (e), the step of forming impurity layers in portions of the active region located below both sides of the gate electrode, respectively.

In the method for fabricating a semiconductor device according to the present invention, the semiconductor material forming the gate electrode and the interconnect may be polysilicon or amorphous silicon.

As described above, with the present invention, the silicide layer is formed also on the interconnect such as the gate interconnect on the isolation. Therefore, as compared to the conventional device structure in which only the upper surface of the gate electrode wiring is silicided, the area of the silicided region is greater by the area of the silicided side surface of the interconnect. This prevents resistance rise of the gate electrode wiring resulting from a break of the silicide layer on the gate electrode wiring. Moreover, the silicide layer is provided on the side surface of part of the interconnect which serves as the connecting portion between the n- and p-type gate electrodes of the dual gate structure, which prevents resistance rise of the gate electrode wiring resulting from a break of the silicide layer of the connecting portion. Furthermore, the silicide layer is provided on the side surface of the interconnect which serves as the contact portion such as the gate contact. Thereby, even if the position of the contact plug deviates and thus a portion of the contact plug is located off the interconnect such as the gate interconnect, the contact area with the contact plug can be secured on both the upper and side surfaces of the gate interconnect. This avoids the trouble in which the contact resistance therebetween increases. In addition, unlike the conventional technique, there is no need to provide a design rule about the contact portion of the gate interconnect with a margin region for the deviation having a fixed area in order to secure a sufficient contact area with the contact plug. This facilitates a decrease in the distance between adjacent lines of the gate electrode wiring, so that the chip area of the device can be reduced.

As is apparent from the above, the present invention relates to a semiconductor device and its fabrication method, and application of the present invention to a semiconductor device with a silicide layer provided on a surface of a gate electrode offers an extremely useful effect of preventing resistance rise of the gate electrode and a gate contact.

### BRIEF DESCRIPTION OF THE DRAWINGS

FIG. 1 is a plan view showing the structure of a semiconductor device according to a first embodiment of the present invention.

FIGS. 2A to 2D are sectional views showing process steps of a method for fabricating a semiconductor device according to the first embodiment of the present invention.

FIG. 3 is a plan view showing the structure of a semiconductor device according to a second embodiment of the present invention.

FIG. 4 is a sectional view showing one process step of a method for fabricating a semiconductor device according to the second embodiment of the present invention.

FIG. 5 is a plan view showing the structure of a semiconductor device according to a modification of the second embodiment of the present invention.

FIG. 6 is a sectional view taken along the line V-V in FIG. 5.

FIG. 7 is a plan view showing the structure of a semiconductor device according to a third embodiment of the present invention.

FIG. 8 is a sectional view taken along the line VIIa-VIIa in FIG. 7.

FIG. 9 is a sectional view taken along the line VIIb-VIIb in FIG. 7.

FIG. 10 is a plan view showing the structure of a semiconductor device according to a fourth embodiment of the present invention.

FIG. 11 is a sectional view taken along the line Xa-Xa in FIG. 10.

FIG. 12 is a sectional view taken along the line Xb-Xb in FIG. 10.

FIG. 13 is a plan view showing the structure of a semiconductor device according to a fifth embodiment of the present invention.

FIG. 14 is a sectional view taken along the line XIIIa-XIIIa in FIG. 13.

FIG. 15 is a sectional view taken along the line XIIIb-XIIIb in FIG. 13.

FIG. 16 is a plan view showing the structure of a conventional semiconductor device.

FIGS. 17A to 17C are sectional views showing process steps of a conventional method for fabricating a semiconductor device.

FIG. 18 is a view for explaining one problem of the conventional semiconductor device.

FIG. 19 is a view for explaining another problem of the conventional semiconductor device.

### DETAILED DESCRIPTION OF THE PREFERRED EMBODIMENTS

### First Embodiment

A semiconductor device and its fabrication method according to a first embodiment of the present invention will be described below with reference to the accompanying drawings.

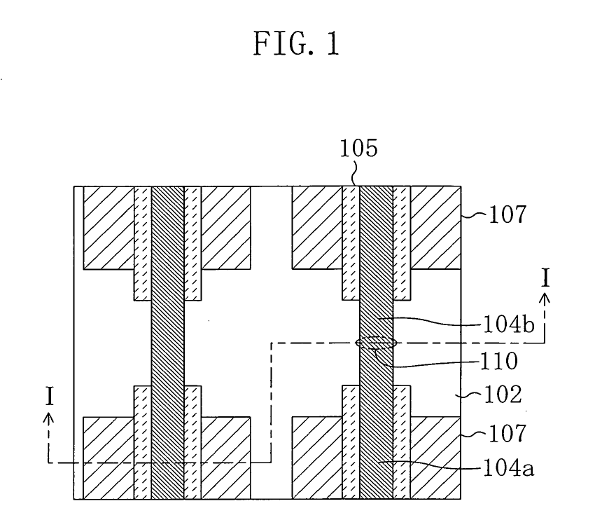

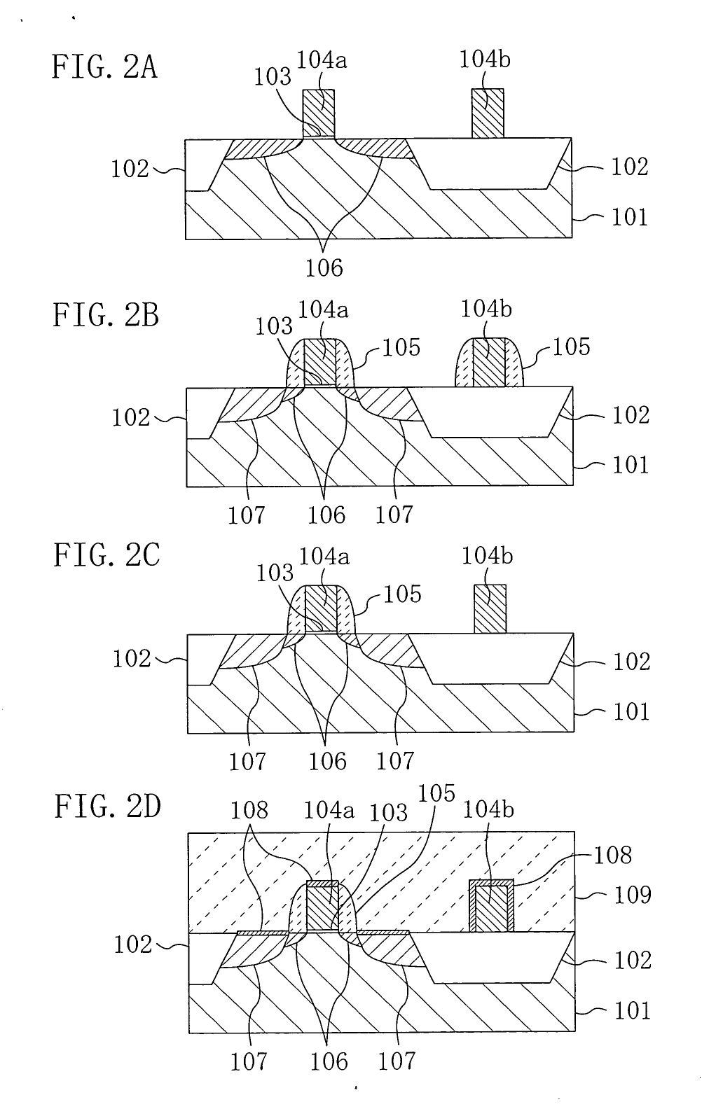

FIG. 1 is a plan view showing the structure of the semiconductor device according to the first embodiment, and FIGS. 2A to 2D are sectional views showing process steps of the fabrication method of the semiconductor device in FIG. 1 according to the first embodiment. Note that FIGS. 2A to 2D illustrate cross-sectional structures taken along the line I-I in FIG. 1.

The fabrication method of the semiconductor device in FIG. 1 according to the first embodiment is as follows. First, as shown in FIG. 2A, by an STI (shallow trench isolation) method or the like, an isolation insulating film 102 for electrically isolating elements from each other is formed in a semiconductor substrate 101. Then, using the isolation insulating film 102 as a mask, the semiconductor substrate 101 is subjected to impurity implantation for a well region formation and the like, and then the semiconductor substrate 101 is subjected to gate oxidation by, for example, a thermal oxidation method. Thereby, on a region of the semiconductor substrate 101 surrounded with the isolation insulating film 102, that is, on an active region serving as an element formation region, a gate insulating film 103 is formed which is made of, for example, a SiO₂ film with a thickness of 2 nm. Subsequently, over the entire surface of the semiconductor substrate 101, that is, on the isolation insulating film 102 and the gate insulating film 103, for example, a 200 nm-thick polysilicon film serving as a gate electrode is grown by a CVD (chemical vapor deposition) method or the like. By ion implantation or the like, an impurity is introduced into the grown polysilicon film. On the resulting polysilicon film, for example, a silicon oxide film (not shown) with a thickness of 100 nm is formed by a CVD method or the like, and then by photolithography and dry etching methods, the formed silicon oxide film is patterned to have the shape of a gate electrode. Using the patterned silicon oxide film as a mask, the polysilicon film and the gate insulating film 103 are dry etched to form a gate electrode 104a which is made of the patterned polysilicon film and which is located above the active region with the gate insulating film 103 interposed therebetween. During this formation, on the isolation insulating film 102, a gate interconnect 104b made of the patterned polysilicon film is formed to make a connection to the gate electrode 104a. In this process, the thickness of the silicon oxide film formed on the polysilicon film and serving as the etching mask is set at a value capable of being removed prior to a silicide layer formation step which will be conducted later. Next, by ion implantation, first doped layers 106 serving as extension regions are formed in portions of the active region located below both sides of the gate electrode 104a, respectively. In the following description, sometimes the gate electrode 104a and the gate interconnect 104b are combinedly referred to as gate electrode wiring 104.

Over the entire surface of the semiconductor substrate 101, for example, a silicon oxide film with a thickness of 10 nm and, for example, a silicon nitride film with a thickness of 100 nm are sequentially formed by a CVD method or the like. The silicon nitride film and the silicon oxide film are then subjected to anisotropic etching to remove portions of the silicon oxide film and the silicon nitride film other than portions thereof formed on the side surfaces of the gate electrode wiring 104. Thereby, as shown in FIG. 2B, insulating sidewalls 105 are formed on the side surfaces of the gate electrode wiring 104, respectively. Subsequently, by a photolithography method, an ion implantation method, and a heat treatment for activating implanted impurities, second doped layers 107 serving as source and drain regions are formed in portions of the active region located below the both sides of the gate electrode 104a, respectively. In the first embodiment, in order to form a dual gate structure, an n-type doped layer and a p-type doped layer are formed as the second doped layer 107 and an n-type gate electrode and a p-type gate electrode are formed as the gate electrode 104a. In FIG. 1, as a concrete example, a connecting portion 110 between the n- and p-type gate electrodes is shown. That is to say, the connecting portion 110 is the gate interconnect 104b connecting the gate electrode 104a as the n-type gate electrode to the gate electrode 104a as the p-type gate electrode.

As shown in FIG. 2C, for example, by photolithography and wet etching methods, the insulating sidewalls 105 are selectively removed which are formed on the side surfaces of at least a portion of the gate interconnect 104b on the isolation insulating film 102. In the first embodiment, the portion of the gate interconnect 104b on which the insulating sidewall 105 has been removed (that is, the portion of the gate interconnect 104b whose side surface will be formed with a silicide layer 108 (see FIG. 2D)) agrees with the connecting portion 110 between the n- and p-type gate electrodes of the dual gate structure.

A native oxide film existing on the surfaces of silicon layers serving as the gate electrode wiring 104 and as the second doped layer 107 is removed, and then over the entire surface of the semiconductor substrate 101, for example, a titanium film with a thickness of 20 nm is deposited by a sputtering method or the like. The resulting semiconductor substrate 101 is subjected to, for example, RTA (rapid thermal annealing) at 700° C. or lower in a nitrogen atmosphere or the like. Thereby, silicon forming the gate electrode wiring 104 and the semiconductor substrate 101 is allowed to react with a titanium film portion in contact with the silicon to produce titanium silicide. This forms, on the surface of the polysilicon film serving as the gate electrode wiring 104 and the surface of the second doped layer 107, a titanium silicide layer with a low resistance. Thereafter, the semiconductor substrate 101 is immersed in an etching solution such as a hydrogen peroxide solution to selectively remove unreacted titanium remaining on the isolation insulating film 102, the insulating sidewalls 105, and the like. Then, the resulting semiconductor substrate 101 is subjected to an RTA at a higher temperature (for example, 700° C. or higher) than the temperature of the RTA described above, which forms, as shown in FIG. 2D, the silicide layer 108 on the upper surface of the gate electrode 104a, the upper and side surfaces of the gate interconnect 104b, and the surfaces of the second doped layers 107 as the source and drain regions. An interlayer insulating film 109 made of, for example, an oxide film is then formed over the entire surface of the semiconductor substrate 101. In the manner described above, the semiconductor device of the first embodiment shown in FIG. 1 is completed. Note that illustration of the silicide layer 108 and the interlayer insulating film 109 is omitted in FIG. 1.

As described above, in the first embodiment, of the insulating sidewalls 105 formed on the side surfaces of the gate electrode wiring 104, only those formed on the side surfaces of the gate interconnect 104b on the isolation insulating film 102 are removed. This enables formation of the silicide layer 108 on not only the upper surface but also the side surfaces of the gate interconnect 104b. Therefore, as compared to the conventional device structure in which only the upper surface of the gate electrode wiring is silicided, the area of the silicided region is greater by the area of the silicided side surfaces of the gate interconnect 104b. This reduces the resistance of the gate electrode wiring 104 and prevents resistance rise of the gate electrode wiring 104 resulting from a break of the silicide layer 108.

Moreover, in the first embodiment, the portion of the gate interconnect 104b whose side surface is formed with the silicide layer 108 is located at the connecting portion 110 between the n- and p-type gate electrodes of the dual gate structure. Therefore, the area of the silicided region of the connecting portion 110 is increased, so that resistance rise of the gate electrode wiring 104 resulting from a break of the silicide layer 108 of the connecting portion 110 can be prevented.

In the first embodiment, polysilicon is employed as the material for the gate electrode wiring 104. Instead of this, for example, amorphous silicon, or another semiconductor material containing silicon may be employed thereas.

In the first embodiment, titanium is employed as metal for forming the silicide layer 108. Instead of this, metal for silicidation such as cobalt, tungsten, or nickel may be employed thereas.

In the first embodiment, the stacked structure of a silicon oxide film and a silicon nitride film is employed as the insulating sidewall 105. Instead of this, only the silicon oxide film or only the silicon nitride film may be employed thereas.

In the first embodiment, a wet etching method is used to remove the insulating sidewalls 105 formed on the side surfaces of the gate interconnect 104b. Instead of this, a dry etching method may be used. However, the etching for removing the insulating sidewalls 105 is preferably an isotropic etching, and from this regard, it is desirable to use a wet etching. In either of the wet and dry etching methods, it is preferable to perform etching having the selectivity over the isolation insulating film 102. In removing the insulating sidewalls 105 formed on the side surfaces of the gate interconnect 104b, from the viewpoint of preventing a short circuit between the gate interconnect 104b and the source and drain regions or the like, the insulating sidewalls 105 which are formed on the side surfaces of part of the gate interconnect 104b located in the vicinity of the active region are preferably left.

### Second Embodiment

A semiconductor device and its fabrication method according to a second embodiment of the present invention will be described below with reference to the accompanying drawings.

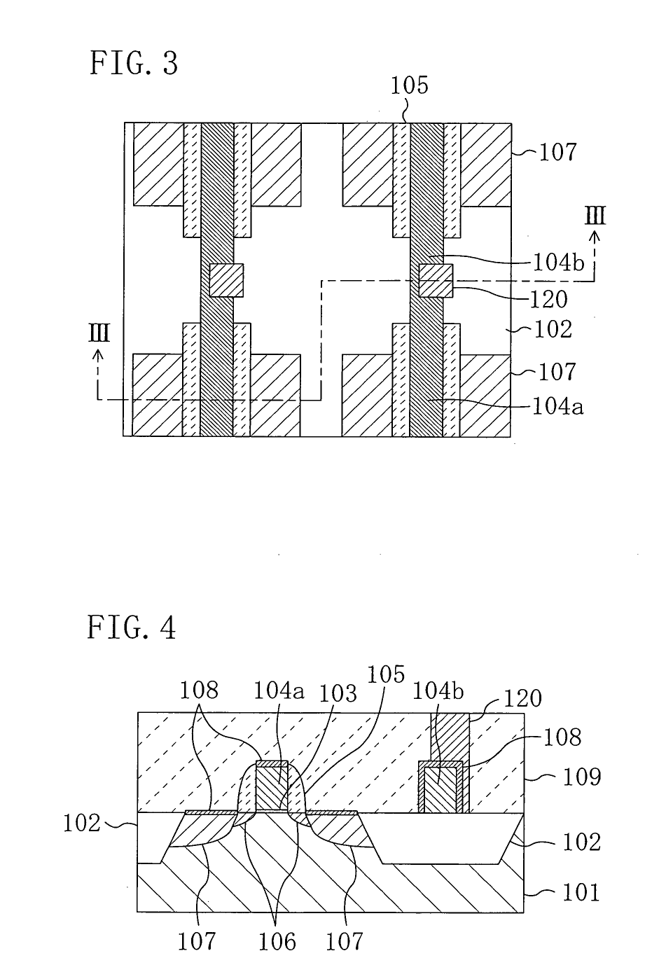

FIG. 3 is a plan view showing the structure of the semiconductor device according to the second embodiment, and FIG. 4 is a sectional view showing one process step of the fabrication method of the semiconductor device in FIG. 3 according to the second embodiment. Note that FIG. 4 is a sectional view taken along the line III-Ill in FIG. 3. In the fabrication method of the semiconductor device according to the second embodiment, the same process steps as the semiconductor device fabrication method of the first embodiment shown in FIGS. 2A to 2D are carried out prior to the step shown in FIG. 4.

Specifically, the fabrication method of the semiconductor device in FIG. 3 according to the second embodiment is as follows. First, the same process steps as the semiconductor device fabrication method of the first embodiment shown in FIGS. 2A to 2D are carried out. Thereafter, as shown in FIG. 4, by photolithography and dry etching methods, a contact hole reaching the gate interconnect 104b on the isolation insulating film 102 is formed through the interlayer insulating film 109, and then by a CVD method or the like, the formed contact hole is filled with tungsten to form a contact plug 120. In this formation, the width of the contact plug 120 in the direction of the gate length is set at a value equal to or smaller than that of the gate interconnect 104b. Note that in the second embodiment, the contact plug 120 is formed on a portion of the gate interconnect 104b whose side surface is also formed with a silicide layer 108, that is, on a portion of the gate interconnect 104b where the insulating sidewall 105 has been removed. In the manner described above, the semiconductor device of the second embodiment shown in FIG. 3 is completed. Note that illustration of the silicide layer 108 and the interlayer insulating film 109 is omitted in FIG. 3.

With the second embodiment, even if the position of the contact plug 120 deviates relative to the gate interconnect 104b and thus a portion of the contact plug 120 is located off the gate interconnect 104b, the contact area of the gate interconnect 104b with the contact plug 120 can be secured on both the upper and side surfaces of the gate interconnect 104b. This avoids the trouble in which the contact resistance therebetween increases. In addition, in the conventional technique, in order to secure a sufficient contact area of the gate interconnect 104b with the contact plug 120, a design rule about the contact portion of the gate interconnect 104b has to be provided with a margin region for the deviation having a fixed area. However, with the second embodiment, there is no need to provide such a region. This facilitates a decrease in the distance between adjacent lines of the gate electrode wiring 104, so that the chip area of the device can be reduced.

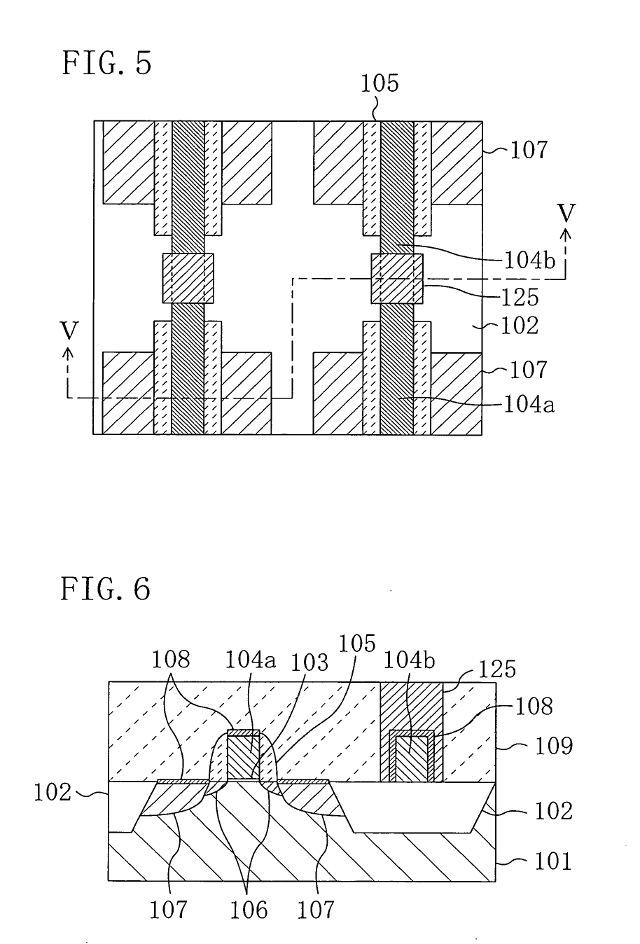

Furthermore, with the second embodiment, electrical contact can be established also at the side surface of the gate interconnect 104b, which provides the effect of enlarging the contact plug without hindering miniaturization of the device. To be more specific, FIG. 5 is a plan view illustrating the case where in the semiconductor device of the second embodiment shown in FIG. 3, instead of the contact plug 120, a contact plug 125 having a larger width in the direction of the gate length than the gate interconnect 104b is provided over the gate interconnect 104b. FIG. 6 is a sectional view taken along the line V-V in FIG. 5. Unlike the case (see FIGS. 3 and 4) where the contact plug 120 having a width in the direction of the gate length equal to or smaller than that of the gate interconnect 104b is provided, as shown in FIGS. 5 and 6, the contact plug 125 having a greater width in the direction of the gate length than the gate interconnect 104b can be provided without changing the design rule about the gate electrode wiring 104. Thus, a more reliable electrical contact with the gate electrode wiring 104 can be established without sacrificing miniaturization of the device.

### Third Embodiment

A semiconductor device and its fabrication method according to a third embodiment of the present invention will be described below with reference to the accompanying drawings.

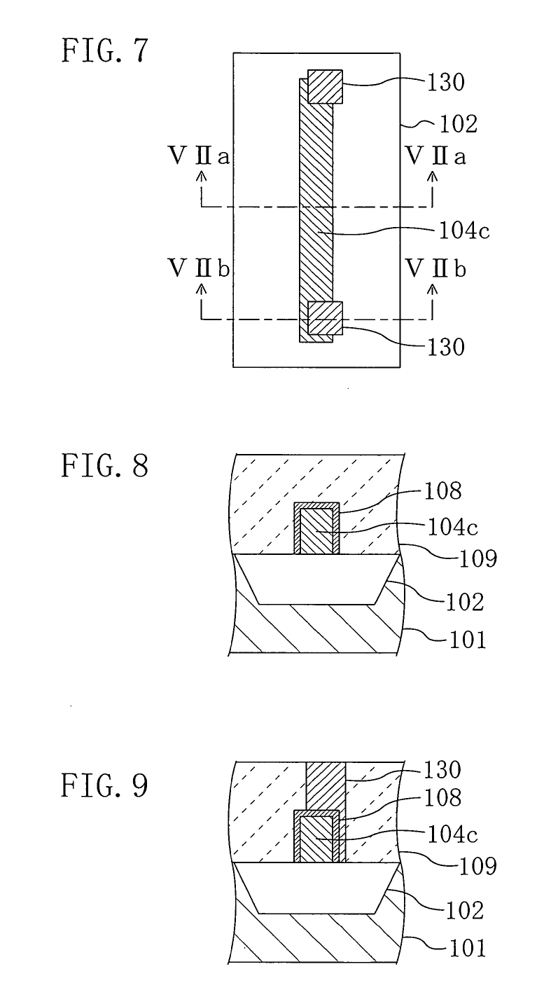

FIG. 7 is a plan view showing the structure of the semiconductor device according to the third embodiment, and FIGS. 8 and 9 are sectional views taken along the lines VIIIa-VIIa and VIIb-VIIb in FIG. 7, respectively.

As shown in FIGS. 7 to 9, the third embodiment differs from the first and second embodiments in that an interconnect 104c made of the same material as the gate electrode 104a is provided on the isolation insulating film 102 and in the same layer as the gate electrode 104a. In this structure, while the gate interconnect 104b is directly connected to the gate electrode 104a (see FIG. 1 or 3), the interconnect 104c is electrically connected to the gate interconnect 104b through another interconnect (not shown) provided in a different layer (an upper layer) from the gate electrode 104a and through a contact plug 130 connecting another said interconnect to the interconnect 104c. In addition, the interconnect 104c is formed in the same step as the formation step of the gate electrode 104a and the gate interconnect 104b (the step of the first embodiment shown in FIG. 2A). In this structure, the contact plug 130 may have a width equal to, or larger or smaller than the line width (of the shorter side) of the interconnect 104c.

Note that FIGS. 7 to 9 show only a region of the device where the interconnect 104c is formed (resistor region). In FIG. 7, illustration of the silicide layer 108 and the interlayer insulating film 109 is omitted. Although not shown, in the third embodiment, a region where the gate electrode 104a and the gate interconnect 104b are formed (transistor region) is arranged in the same location as those of the first and second embodiments.

In the third embodiment, in the step of forming the insulating sidewall 105 on the respective side surfaces of the gate electrode 104a and the gate interconnect 104b (the step of the first embodiment shown in FIG. 2B), the insulating sidewall 105 is also formed on the side surface of the interconnect 104c. However, as shown in FIG. 7, the insulating sidewall 105 on the side surface of the interconnect 104c is fully removed in the step of removing the insulating sidewall 105 on the side surface of the gate interconnect 104b (the step of the first embodiment shown in FIG. 2C). As a result, as shown in FIGS. 8 and 9, in the step of siliciding the gate electrode 104a and the gate interconnect 104b (the step of the first embodiment shown in FIG. 2D), the silicide layer 108 is formed on the entire upper and side surfaces of the interconnect 104c. Note that the step of forming the contact plug 130 on the interconnect 104c may be carried out simultaneously with or separately from the step of forming the contact plug 120 above the gate interconnect 104b (the step of the second embodiment shown in FIG. 4).

With the third embodiment, since not only the upper surface but also the side surface of the interconnect 104c can be silicided, the effect of forming the interconnect 104c with a low resistance can be provided in addition to the effects of the first and second embodiments. Moreover, even if the position of the contact plug 130 deviates relative to the interconnect 104c and thus a portion of the contact plug 130 is located off the interconnect 104c, the contact area of the interconnect 104c with the contact plug 130 can be secured on both the upper and side surfaces of the interconnect 104c. This avoids the trouble in which the contact resistance therebetween increases. In addition, in the conventional technique, in order to secure a sufficient contact area of the interconnect 104c with the contact plug 130, a design rule about the contact portion of the interconnect 104c has to be provided with a margin region for the deviation having a fixed area. However, with the third embodiment, there is no need to provide such a region. This facilitates a decrease in the distance between adjacent lines of the gate electrode wiring 104 including the interconnect 104c, so that the chip area of the device can be reduced.

In the third embodiment, the interconnect 104c is designed to be electrically connected to the gate interconnect 104b. Instead of this, the interconnect 104c may be designed to be electrically connected to the source and drain regions or the like.

### Fourth Embodiment

A semiconductor device and its fabrication method according to a fourth embodiment of the present invention will be described below with reference to the accompanying drawings.

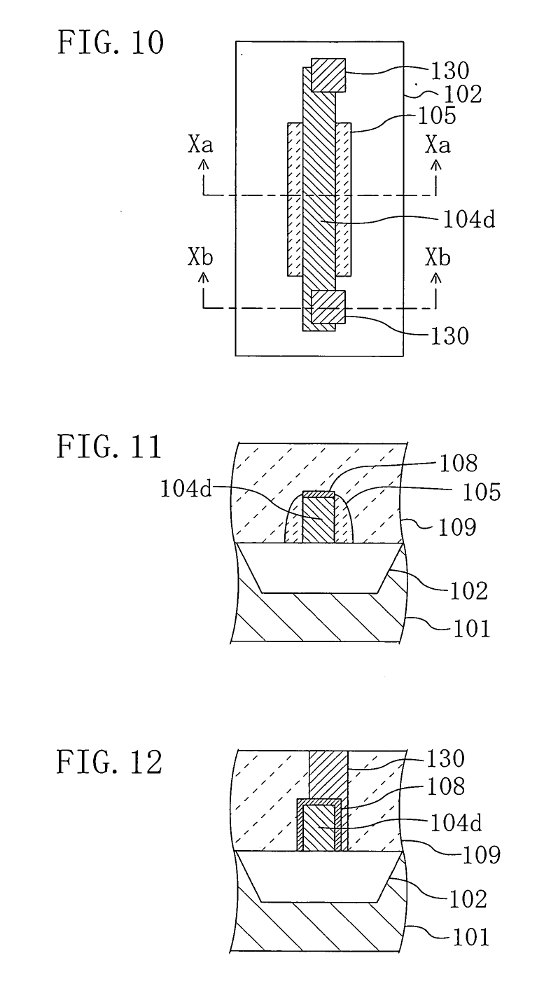

FIG. 10 is a plan view showing the structure of the semiconductor device according to the fourth embodiment, and FIGS. 11 and 12 are sectional views taken along the lines Xa-Xa and Xb-Xb in FIG. 10, respectively.

As shown in FIGS. 10 to 12, the fourth embodiment differs from the first and second embodiments in that a resistor interconnect 104d made of the same material as the gate electrode 104a is provided on the isolation insulating film 102 and in the same layer as the gate electrode 104a. In this structure, while the gate interconnect 104b is directly connected to the gate electrode 104a (see FIG. 1 or 3), the resistor interconnect 104d is electrically connected to the gate interconnect 104b through another interconnect (not shown) provided in a different layer (an upper layer) from the gate electrode 104a and through the contact plug 130 connecting another said interconnect to the resistor interconnect 104d. In addition, the resistor interconnect 104d is formed in the same step as the formation step of the gate electrode 104a and the gate interconnect 104b (the step of the first embodiment shown in FIG. 2A). In this structure, the contact plug 130 may have a width equal to, or larger or smaller than the line width (of the shorter side) of the resistor interconnect 104d.

Note that FIGS. 10 to 12 show only a region of the device where the resistor interconnect 104d is formed (resistor region). In FIG. 10, illustration of the silicide layer 108 and the interlayer insulating film 109 is omitted. Although not shown, in the fourth embodiment, a region where the gate electrode 104a and the gate interconnect 104b are formed (transistor region) is arranged in the same location as those of the first and second embodiments.

In the fourth embodiment, in the step of forming the insulating sidewall 105 on the respective side surfaces of the gate electrode 104a and the gate interconnect 104b (the step of the first embodiment shown in FIG. 2B), the insulating sidewall 105 is also formed on the side surface of the resistor interconnect 104d. However, as shown in FIG. 10, of the insulating sidewalls 105 on the side surfaces of the resistor interconnect 104d, portions thereof at which the contact plug 130 will be formed are removed in the step of removing the insulating sidewall 105 on the side surface of the gate interconnect 104b (the step of the first embodiment shown in FIG. 2C). As a result, as shown in FIGS. 11 and 12, in the step of siliciding the gate electrode 104a and the gate interconnect 104b (the step of the first embodiment shown in FIG. 2D), the silicide layer 108 is formed on portions of the upper and side surfaces of the resistor interconnect 104d on which the insulating sidewalls 105 have been removed. Note that the step of forming the contact plug 130 on a portion of the resistor interconnect 104d on which the insulating sidewall 105 has been removed, that is, on a portion of the resistor interconnect 104d whose side surface is formed with the silicide layer 108 may be carried out simultaneously with or separately from the step of forming the contact plug 120 above the gate interconnect 104b (the step of the second embodiment shown in FIG. 4).

The fourth embodiment provides the following effects in addition to the effects of the first and second embodiments. Even if the position of the contact plug 130 deviates relative to the resistor interconnect 104d and thus a portion of the contact plug 130 is located off the resistor interconnect 104d, the contact area of the resistor interconnect 104d with the contact plug 130 can be secured on both the upper and side surfaces of the resistor interconnect 104d. This avoids the trouble in which the contact resistance therebetween increases. In addition, in the conventional technique, in order to secure a sufficient contact area of the resistor interconnect 104d with the contact plug 130, a design rule about the contact portion of the resistor interconnect 104d has to be provided with a margin region for the deviation having a fixed area. However, with the fourth embodiment, there is no need to provide such a region. This facilitates a decrease in the distance between adjacent lines of the gate electrode wiring 104 including the resistor interconnect 104d, so that the chip area of the device can be reduced.

In the fourth embodiment, a region of the resistor interconnect 104d whose side surface is formed with the insulating sidewall 105 is used as a resistor. However, since the entire upper surface of the resistor interconnect 104d is silicided, the resistance of the resistor interconnect 104d is relatively low.

In the fourth embodiment, the resistor interconnect 104d is designed to be electrically connected to the gate interconnect 104b. Instead of this, the resistor interconnect 104d may be designed to be electrically connected to the source and drain regions or the like.

### Fifth Embodiment

A semiconductor device and its fabrication method according to a fifth embodiment of the present invention will be described below with reference to the accompanying drawings.

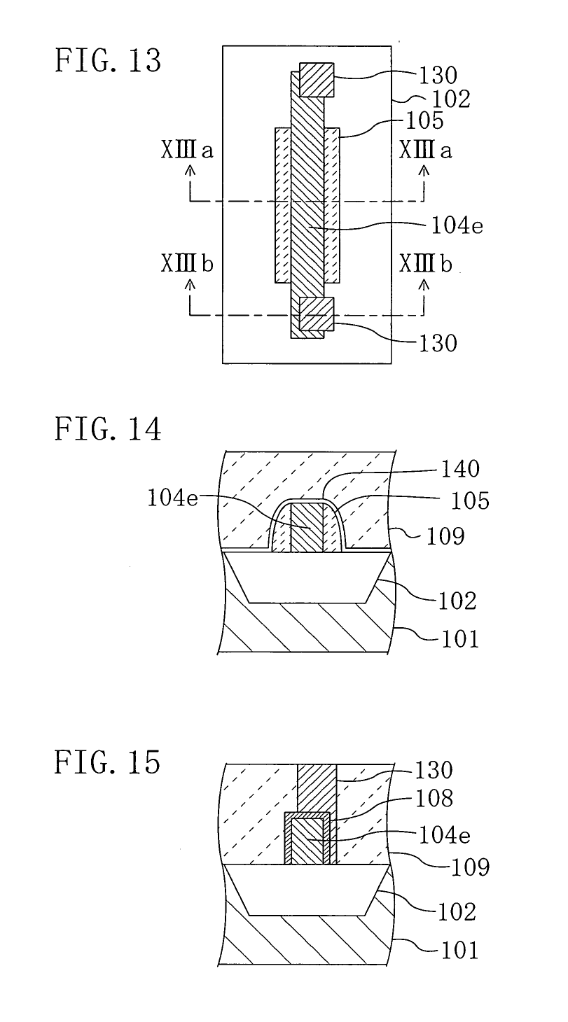

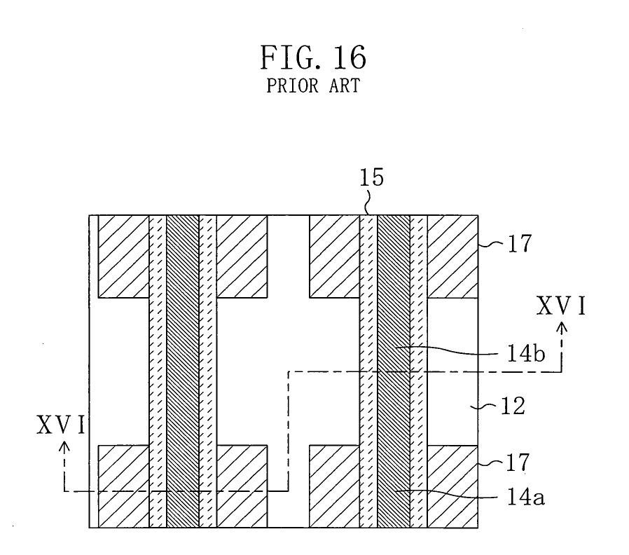

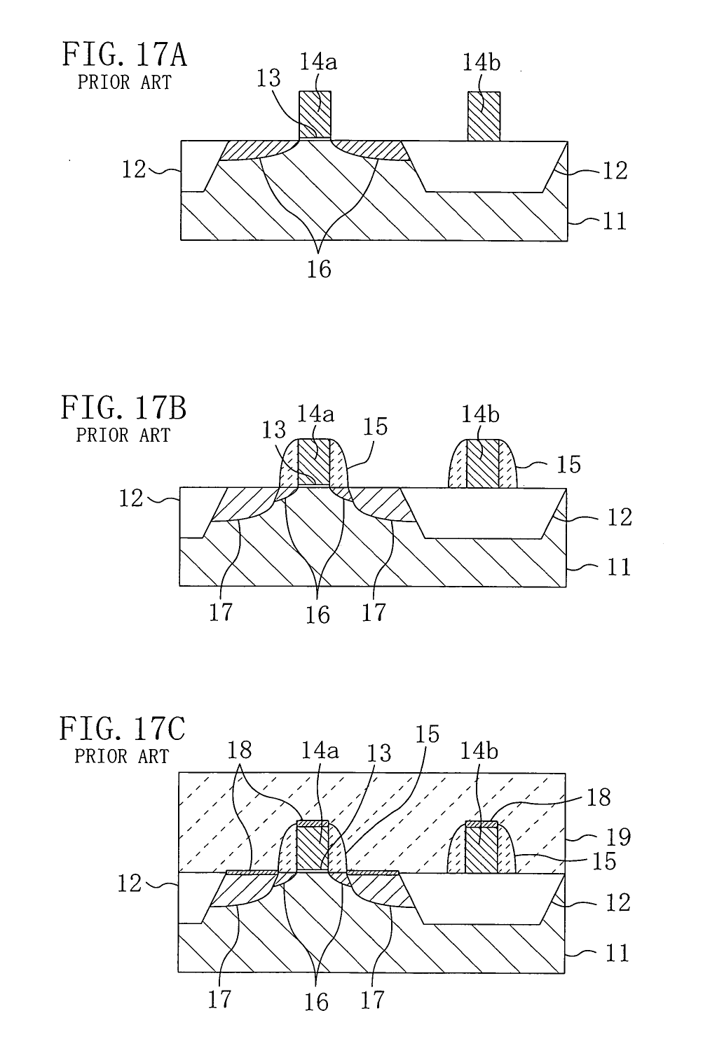

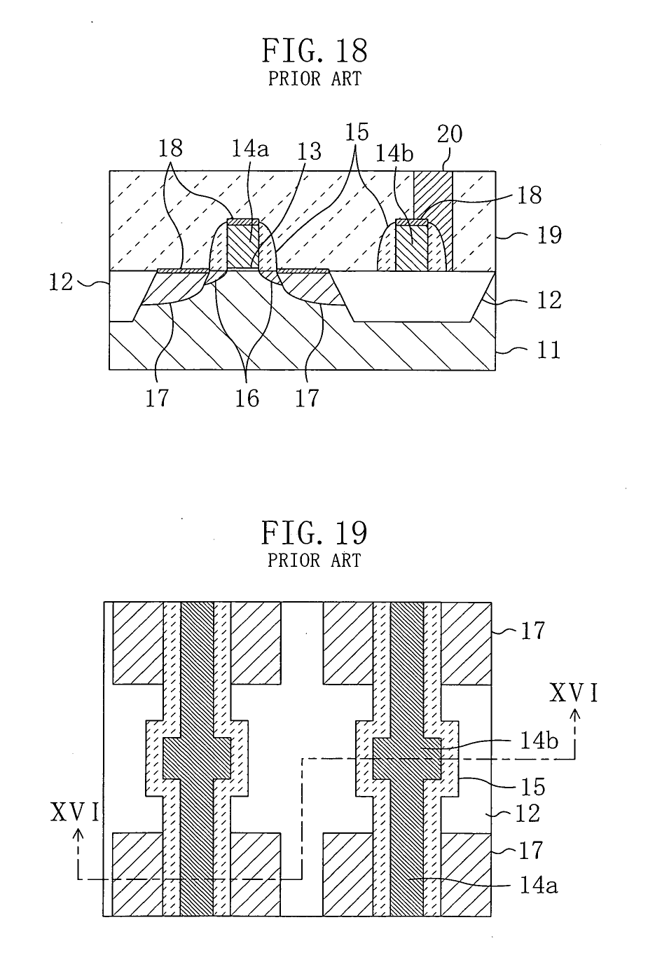

FIG. 13 is a plan view showing the structure of the semiconductor device according to the fifth embodiment, and FIGS. 14 and 15 are sectional views taken along the lines XIIa-XIIIa and XIIIb-XIIIb in FIG. 13, respectively.

As shown in FIGS. 13 to 15, the fifth embodiment differs from the first and second embodiments in that a resistor interconnect 104e made of the same material as the gate electrode 104a is provided on the isolation insulating film 102 and in the same layer as the gate electrode 104a. In this structure, while the gate interconnect 104b is directly connected to the gate electrode 104a (see FIG. 1 or 3), the resistor interconnect 104e is electrically connected to the gate interconnect 104b through another interconnect (not shown) provided in a different layer (an upper layer) from the gate electrode 104a and through the contact plug 130 connecting another said interconnect to the resistor interconnect 104e. In addition, the resistor interconnect 104e is formed in the same step as the formation step of the gate electrode 104a and the gate interconnect 104b (the step of the first embodiment shown in FIG. 2A). In this structure, the contact plug 130 may have a width equal to, or larger or smaller than the line width (of the shorter side) of the resistor interconnect 104e.

Note that FIGS. 13 to 15 show only a region of the device where the resistor interconnect 104e is formed (resistor region). In FIG. 13, illustration of the silicide layer 108, the interlayer insulating film 109, and an anti-silicidation film 140 (a film for preventing the underlying material from being silicided: see FIG. 14) is omitted. In the fifth embodiment, a region where the gate electrode 104a and the gate interconnect 104b are formed (transistor region) is arranged in the same location as those of the first and second embodiments.

In the fifth embodiment, in the step of forming the insulating sidewall 105 on the respective side surfaces of the gate electrode 104a and the gate interconnect 104b (the step of the first embodiment shown in FIG. 2B), the insulating sidewall 105 is also formed on the side surface of the resistor interconnect 104e. In the fifth embodiment, after this formation step and before the silicidation step, an insulating film such as a silicon oxide film or a silicon nitride film is deposited over the entire surface of the semiconductor substrate 101, and then by photolithography and etching techniques, a portion of the insulating film deposited on a region to be silicided (to become a silicided region) is removed. On the other hand, as shown in FIG. 14, in a portion thereof not to be silicided (to become an unsilicided region), the insulating film is let to remain as the anti-silicidation film 140. That is to say, the silicided region and the unsilicided region are selectively formed depending upon the presence or absence of the anti-silicidation film 140. In the fifth embodiment, as shown in FIG. 14, for example, all portions of the resistor interconnect 104e except the portions formed with the contact plug 130 are located in the unsilicided region, and the anti-silicidation film 140 is provided to cover these portions in the unsilicided region. Subsequently, as shown in FIG. 13, of the insulating sidewalls 105 on the side surfaces of the resistor interconnect 104e, portions thereof at which the contact plug 130 will be formed are removed in the step of removing the insulating sidewall 105 on the side surfaces of the gate interconnect 104b (the step of the first embodiment shown in FIG. 2C). As a result, in the step of siliciding the gate electrode 104a and the gate interconnect 104b (the step of the first embodiment shown in FIG. 2D), as shown in FIG. 15, the silicide layer 108 is formed on the upper and side surfaces of portions of the resistor interconnect 104e on which the insulating sidewalls 105 have been removed. On the other hand, as shown in FIG. 14, on the portion of the resistor interconnect 104e covered with the anti-silicidation film 140, neither the upper surface nor the side surface is silicided. Note that the step of forming the contact plug 130 on the portion of the resistor interconnect 104e on which the insulating sidewall 105 has been removed, that is, on the portion of the resistor interconnect 104e whose side surface is formed with the silicide layer 108 may be carried out simultaneously with or separately from the step of forming the contact plug 120 above the gate interconnect 104b (the step of the second embodiment shown in FIG. 4).

The fifth embodiment provides the following effects in addition to the effects of the first and second embodiments. Even if the position of the contact plug 130 deviates relative to the resistor interconnect 104e and thus a portion of the contact plug 130 is located off the resistor interconnect 104e, the contact area of the resistor interconnect 104e with the contact plug 130 can be secured on both the upper and side surfaces of the resistor interconnect 104e. This avoids the trouble in which the contact resistance therebetween increases. In addition, in the conventional technique, in order to secure a sufficient contact area of the resistor interconnect 104e with the contact plug 130, a design rule about the contact portion of the resistor interconnect 104e has to be provided with a margin region for the deviation having a fixed area. However, with the fifth embodiment, there is no need to provide such a region. This facilitates a decrease in the distance between adjacent lines of the gate electrode wiring 104 including the resistor interconnect 104e, so that the chip area of the device can be reduced.

In the fifth embodiment, the contact formation region of the resistor interconnect 104e where the anti-silicidation film 140 and the insulating sidewalls 105 have been removed is silicided. In contrast to this, the portion of the resistor interconnect 104e covered with the anti-silicidation film 140 and the insulating sidewall 105 is not silicided and serves as a resistor, so that the resistance of the resistor interconnect 104e is relatively high.

In the fifth embodiment, the resistor interconnect 104e is designed to be electrically connected to the gate interconnect 104b. Instead of this, the resistor interconnect 104e is designed to be electrically connected to the source and drain regions or the like.

What is claimed is:

1. A semiconductor device comprising:
an active region formed in a substrate and surrounded with an isolation formed in the substrate;
a gate electrode formed above the active region and made of a semiconductor material; and
an interconnect formed on the isolation and in the same layer as the gate electrode and made of the same material as the gate electrode,
wherein side surfaces of the gate electrode are formed with insulating sidewalls, respectively, and
upper surfaces of the gate electrode and the interconnect and side surfaces of at least a portion of the interconnect are formed with silicide layers, respectively.

2. The device of claim 1,
wherein a contact plug is formed on a portion of the interconnect whose side surface is formed with the silicide layer.

3. The device of claim 2,
wherein the contact plug is connected to at least a portion of the silicide layer formed on the side surface of the interconnect.

4. The device of claim 2,
wherein the contact plug is connected to the silicide layers formed on both side surfaces of the interconnect.

5. The device of claim 1,
wherein the silicide layer is formed on the entire upper and side surfaces of the interconnect.

6. The device of claim 1,
wherein the interconnect is a resistor interconnect, and
the silicide layer is formed on at least side surfaces of contact formation regions located at both ends of the interconnect, the both ends interposing a resistor region of the interconnect.

7. The device of claim 6,
wherein the insulating sidewalls are formed on side surfaces of the resistor region of the interconnect, respectively.

8. The device of claim 7,
wherein an anti-silicidation film is formed to cover an upper surface of the resistor region of the interconnect.

9. The device of claim 1,
wherein a portion of the interconnect whose side surface is formed with the silicide layer is a connecting portion between n- and p-type gate electrodes of a dual gate structure.

10. The device of claim 1,
wherein a gate insulating film is formed between the active region and the gate electrode.

11. The device of claim 1,
wherein impurity layers are formed in portions of the active region located below both sides of the gate electrode, respectively.

12. The device of claim 1,
wherein the semiconductor material forming the gate electrode and the interconnect is polysilicon or amorphous silicon.

13. A method for fabricating a semiconductor device, comprising:
the step (a) of forming, in a substrate, an isolation and an active region surrounded with the isolation;
the step (b) of forming, above the active region, a gate electrode made of a semiconductor material, and simultaneously forming, on the isolation and in the same layer as the gate electrode, an interconnect made of the same material as the gate electrode;
the step (c) of forming insulating sidewalls on side surfaces of the gate electrode and the interconnect;
the step (d) of removing the insulating sidewalls formed on side surfaces of at least a portion of the interconnect; and
the step (e) of forming, after the step (d), silicide layers on upper surfaces of the gate electrode and the interconnect and on portions of side surfaces of the interconnect on which the insulating sidewalls have been removed.

14. The method of claim 13, further comprising, after the step (e), the step of forming a contact plug on a portion of the interconnect whose side surface is formed with the silicide layer.

15. The method of claim 13,
wherein a portion of the interconnect whose side surface is formed with the silicide layer is a connecting portion between n- and p-type gate electrodes of a dual gate structure.

16. The method of claim 13, further comprising, between the steps (a) and (b), the step of forming a gate insulating film on the active region.

17. The method of claim 13, further comprising, between the steps (c) and (e), the step of forming impurity layers in portions of the active region located below both sides of the gate electrode, respectively.

18. The method of claim 13,
wherein the semiconductor material forming the gate electrode and the interconnect is polysilicon or amorphous silicon.
